(19) United States
(12) Patent Application Publication
(10) Pub. No.: US 2016/0181177 A1
(43) Pub. Date: Jun. 23, 2016

(54) Cooling Device for a Current Converter Module

(71) Applicant: VENSYS Elektrotechnik GmbH, 49359 Diepholz (DE)

(72) Inventor: Christoph MEYER, Diepholz (DE)

(21) Appl. No.: 14/974,672

(22) Filed: Dec. 18, 2015

Related U.S. Application Data
(63) Continuation of application No. PCT/EP2014/001659, filed on Jun. 18, 2014.

(30) Foreign Application Priority Data
Jun. 18, 2013 (DE) 10 2013 010 087.9

(51) Int. Cl. H01L 23/473; F28D 1/02; H01L 29/739; F28D 15/00; H01L 23/367; H01L 23/373

(52) U.S. Cl. CPC H01L 23/473; H01L 23/3675; H01L 23/373; H01L 29/7393; F28D 15/00; F28D 1/0246

(57) ABSTRACT

In order to keep the temperature difference on the heat exchanger in a cooling device for a current converter module as low as possible, a cooling device has a cooling liquid channel, which conducts a liquid coolant and which is connected to a cooling circuit, a heat exchanger, which is connected in the cooling circuit and to which a power component is coupled in a thermally conductive manner, and a cooler for cooling the liquid coolant, which cooler is connected in the cooling circuit, wherein a plurality of pipelines is connected in parallel in the heat exchanger in such a way that the temperature difference on the heat exchanger does not exceed a specified quantity.

### RELATED APPLICATIONS

This is a continuation application of International Application No. PCT PCT/EP2014/001659 filed on Jun. 18, 2014, claiming the priority benefit of Germany Application No. 10 2013 010 087.9, filed on Jun. 18, 2013, both of which are hereby incorporated by reference.

### FIELD OF THE INVENTION

The invention relates to a cooling device for a current converter module.

### BACKGROUND OF THE INVENTION

In the case of systems to generate electrical energy, for instance wind power systems or solar power systems, current converter modules are used, which convert the generated direct voltage or alternating voltage to a voltage that has the frequency required by the grid connection point. Depending upon the application case, these types of converters can have a power transfer of several kW to several MW. Located inside the current converter module are fast-switching power semiconductors, for example bipolar transistors with insulated-gate bipolar transistor (IGBT for short). The heat that develops based on conversion losses is dissipated at one or more heat sinks. This heat must he dissipated by a corresponding cooling device so that the power semiconductor is not destroyed due to overheating.

The heat dissipated at the heat sinks is preferably conveyed directly to a heat exchanger, through which a cooling liquid flows. For example, a water/ethanol mixture or a water/glycol mixture is used as a cooling liquid to protect against corrosion or frost.

The cooling liquid is supplied in a cooling circuit, in turn, to an air cooler and correspondingly cooled there, before being led back, in turn, via a pump to the heat exchanger of the power semiconductor.

A problem with such a cooling circuit can be a condition where the temperature difference on the heat exchanger between the supply temperature and the return temperature increases too fast. The result of this is a strong temperature gradient on the heat exchanger, which can cause damage to or even destroy electronic components.

Therefore, the problem addressed by the invention is keeping the temperature difference on the heat exchanger in a cooling device for a current converter module as low as possible.

This problem is solved by the features of the present invention.

Additional embodiments are disclosed of the present invention are disclosed herein.

### BRIEF DESCRIPTION OF THE DRAWINGS

Further details and advantages of the invention are explained based on the following figures, which show:

FIG. 1 A simplified diagram of the cooling device according to the invention, and

FIG. 2 A simplified diagram of the heat exchanger used according to FIG. 1.

### DETAILED DESCRIPTION OF THE INVENTION

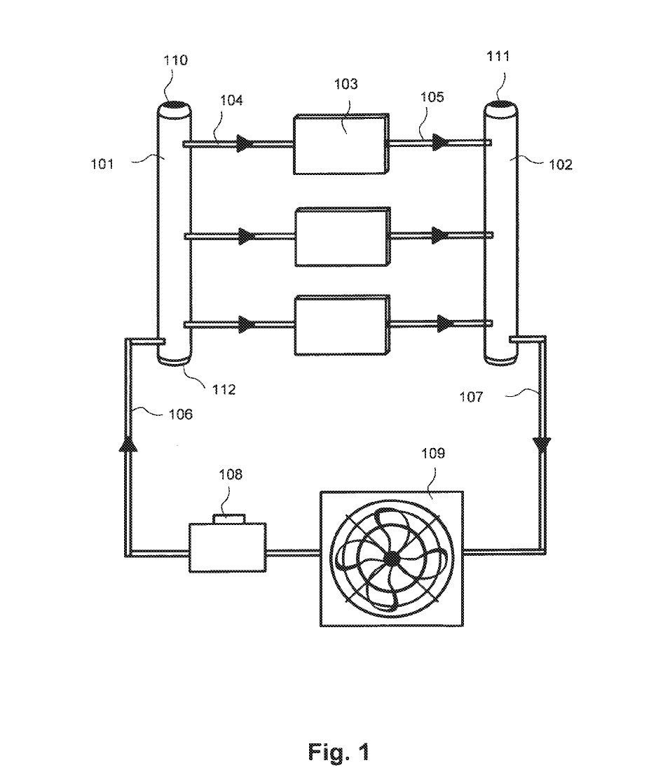

FIG. 1 shows a simplified diagram of the cooling device according to the invention.

The cooling device according to the invention consists overall of a cooling circuit operated with a liquid coolant. A water/ethanol mixture is used as the coolant. In addition, a corrosion inhibitor is added to the coolant. The inhibitor keeps the lime in the water suspended in the solution and protects the steel, aluminum and cooper materials of the cooling device through the formation of a protective film (oxygen diffusion).

As an example, it is assumed that the cooling device is provided for a current converter module of a wind power system or a solar power system for network supply. These types of current converter modules must be designed for powers of several kW up to several MW and have a plurality of power components. In particular, in the top power class of several MW, it is advantageous if a power component is respectively coupled with a heat exchanger and a cooling liquid channel.

As an example, it is further assumed that 3 IGBTs are supposed to be cooled in the cooling circuit. Of course, the invention is also applicable to the cooling of only one IGBT or to any desired plurality of IGBTs.

For reasons of simplicity, only one IGBT of the 3 IGBTs together with the associated heat exchanger is identified with reference sign 103. The heat exchanger 103 of said IGBT is connected via the cooling liquid channel 104 in the feed line (i.e., viewed in the flow direction of the liquid coolant behind the cooler and in front of the heat exchanger) to a perpendicularly mounted (i.e., parallel to the gravity vector) distributor pipe 101. The flow cross-section of the distributor pipe 101 is greater than the flow cross-section of the inlet and outlet cooling liquid channels.

In a corresponding manner, the heat exchanger 103 of said IGBT is connected via the cooling liquid channel 105 in the return line (i.e., viewed in the flow direction of the liquid coolant behind the heat exchanger and in front of the cooler) to a likewise perpendicularly mounted (i.e., parallel to the gravity vector) distributor pipe 102. The flow cross-section of the distributor pipe 102 is in turn greater than the flow cross-sections of the inlet and outlet cooling liquid channels.

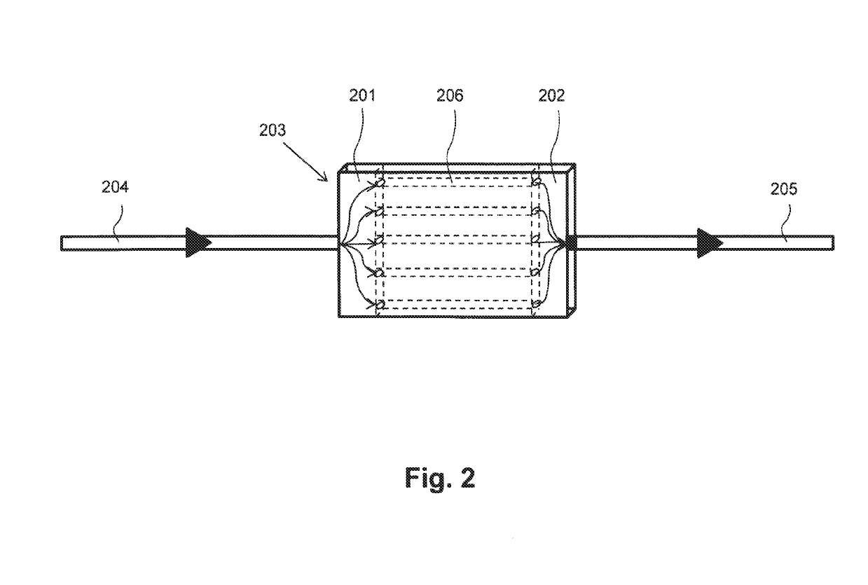

The function of the heat exchanger is explained in further detail below based on FIG. 2. At this point, the mounting direction of the heat exchanger will also be discussed with reference to the gravity vector. The depictions in FIG. 1 and FIG. 2 show a mounting direction parallel to the gravity vector (i.e., the gravity vector lies in the drawing plane). This mounting direction is often necessary for space reasons (and was selected in this case for presentation purposes), but is in no way mandatory for the function of the overall cooling device. A disadvantage of this mounting direction is the fact that air bubbles can possibly accumulate in the upper portion of each heat exchanger 103. Another possibility of each heat exchanger 103 is therefore the mounting direction perpendicular to the gravity vector, i.e., the gravity vector is then perpendicular on the plane of each heat exchanger 103. In this case, air bubbles distribute themselves uniformly in the heat exchanger and can be released again immediately via the cooling liquid.

The coolant for the return line is collected in the distributor pipe 102 and is guided via the cooling liquid channel 107 to an air cooler 109. The air cooler 109 cools down the temperature of the coolant to a required extent and conveys the coolant again to the cooling circuit in the feed line.

Viewed in the flow direction of the coolant, the pump 108 is situated behind the air cooler 109, and said pump supports and maintains the circulation of the coolant within the cooling circuit. If one would like to utilize the natural convection of the cooling liquid for the circulation of the coolant (i.e., warm cooling liquid rises upwards with respect to the gravity vector and cold cooling liquid sinks downward with the gravity vector), it is then necessary for the air cooler 109 to be installed with respect to the gravity vector at the highest point of the cooling circuit. The connection of the air cooler in FIG. 1 must then be modified accordingly.

The coolant finally reaches the feed line again via the cooling liquid channel 106 and therefore the distributor pipe 101, which conveys the cooling liquid to the IGBT 103.

Located above the distributor pipe 101 or 102 is a ventilation valve 110 or 111. The ventilation valve 110 or 111 is controlled mechanically by a membrane, which contracts when dying and expands again when in contact with water.

The ventilation valve 110 or 111 can be installed respectively in both distributor pipes 101 and 102. The functioning of the ventilation valve is still ensured, however, if it is installed either in the distributor pipe 101 or in the distributor pipe 102. The following description relates only to the ventilation valve 110.

If air now gets into the cooling circuit, then the air is transported through the cooling circuit in the form of air bubbles until reaching the distributor pipe 101. The flow cross-section of the distributor pipe 101 is thereby greater than flow cross-section of the cooling liquid channel 104. This causes the flow speed of the coolant in the distributor pipe 101 to be less than the flow speed of the coolant in the cooling liquid channel 104 so that the air bubbles have enough time to rise in the distributor pipe 101 to the ventilation valve 110.

The same also applies to the ventilation valve 111 in the distributor pipe 102 with the flanged-mounted cooling liquid channel 105.

The distributor pipe 102 can he mounted with respect to the gravity vector at the same height as the distributor pipe 101, as shown in FIG. 1. This mounting method is not mandatory however. Another preferred mounting method consists for example of mounting the distributor pipe 102 higher with respect to the gravity vector than the highly mounted heat exchanger. In this way, it is possible for air bubbles that have collected in the heat exchangers or that form there to be transported effectively into the distributor pipe 102 and be vented there via the ventilation valve 111.

There are several possibilities for the design of the ventilation valve. For example, the air release valve can be controlled by a membrane, which contracts in a dry state and therefore opens the air release valve and expands when in contact with water and closes the air release valve. Another possibility consists of connecting the air release valve to a control unit and is opened by the control unit to release air as soon as an air inclusion sensor within the distributor pipe in the vicinity of the air release valve detects an air quantity that exceeds a predetermined amount. The air inclusion sensor can be based for example on the signal of a float gauge, the level of which is evaluated.

Located beneath the distributor pipe 101 or 102 is a heater 112. The heater 112 can consist, for example, of a heating coil leading into the distributor pipe 110, to which current is correspondingly applied as needed.

The purpose of the heater 112 is so that the heat exchanger can be heated as needed via a heating of the coolant, and specifically in case, as an exception, one or more heat exchangers assumes a lower temperature than the ambient air. In addition, appropriate temperature sensors are provided to detect this exceptional case.

Said exceptional case normally occurs if the current converter module is not in operation for example due to maintenance work) and at the same time the ambient air heats up because of external solar radiation (for example during the morning hours). In this case, condensation water forms on the heat exchanger 103 as well as on the heat sinks of the IGBTs and on the IGBT itself, which can cause corrosion or even the destruction of electrical components.

Therefore, if said exceptional case is detected by a control unit, then the control unit switches the heater 112 on. This now causes the heat exchanger 103 not to cool, but rather to heat slightly so that the formation of condensation can he prevented. To maintain the circulating coolant (or now the warming agent), the pump 108 is not necessary in particular when the heater is located with respect to the cooling circuit (or now the heating circuit) in a stand pipe.

FIG. 2 depicts a simplified diagram of the heat exchanger used in accordance with FIG. 1.

The components 203, 204 and 205 correspond to the components 103, 104 and 105 from FIG. 1.

The heat sink of an IGBT is flange-mounted on the rear side of the heat exchanger 203.

Provided inside the heat exchanger 203 are two distributors 201 and 202, between which parallel pipelines 206 are connected. Because of their parallel connection, the parallel pipelines 206 expand the effective flow cross-section of the heat exchanger 203 and simultaneously prevent the formation of turbulent flows. It is preferred that just enough pipelines are connected in parallel in the heat exchanger that the pressure loss on the heat exchanger is not more than 10% of the operating pressure of the cooling circuit.

Overall, the parallel connection of the pipelines within the heat exchanger 103 ensures that the heat exchanger 103 does not constitute too great a flow resistance with respect to the entire cooling circuit so that the temperature difference on the heat exchanger 103 between the feed line 104 and the return line 105 can be kept at a low level.

The temperature difference is preferably always below 10 Kelvin, especially preferably below 5 Kelvin. The low temperature difference in turn ensures that the affected IGBT is uniformly cooled, which increases the service life and reduces the probability of failure.

Adherence to a predetermined temperature difference on the heat exchanger is thus especially desirable. Therefore, there is a need for a technical teaching, which allows a cooling device to he created in a simple manner and without laborious tests, with which the predetermined temperature difference can be adhered to from the outset on the heat exchanger.

Such a technical teaching is possible according to the invention at least if a topology and the boundary conditions of the cooling device can be assumed, as depicted and described in FIG. 1. This means the following in detail:
The cooling device is provided for the cooling of very high power losses (greater than 1 kilowatt per heat exchanger).
A heat exchanger is provided for cooling of a power component (e.g., IGBT).
Situated in the feed line and in the return line is a respective distributor pipe, the flow cross-section of which is greater than the flow cross-sections of the inlet and outlet cooling liquid channels.
The cooler is able to cool e cooling medium with the total power loss that accrues.
The pump is able to maintain a predetermined volume flow \dot{V} in the cooling circuit with bridged heat exchangers (i.e., the heat exchangers are detached for this purpose).

The sought-after heat exchanger should heat the cooling liquid with power loss P_{V}. Therefore, the following energy balance applies for a delta volume ΔV of the cooling liquid within time interval Δt:

P_{V}·Δt=\dot{V}·Δt·ρ·c·ΔT

where P_{V} Power loss
Δt Time interval
\dot{V} Volume flow of the cooling liquid
ρ Density of the cooling liquid
c Specific thermal capacity of the cooling liquid
ΔT Temperature difference on the heat exchanger

The knowledge of the invention consists of the fact that the temperature difference ΔT can actually be adhered to with the above-mentioned boundary conditions and with a plate-shaped heat exchanger, if a plurality of pipelines is connected in parallel in a suitable manner in the heat exchanger. Therefore, the sought-after heater exchanger can be created in a very limited number of tests, in that a plurality of pipelines is connected in parallel in the heat exchanger such that the temperature difference on the heat exchanger does not exceed the predetermined amount ΔT according to the above formula of:

$$Δ T = \frac{Pv}{\dot{V} \cdot ρ \cdot c}$$

A numerical example is given in the following (for the sake of simplicity for the cooling medium of water at 20° C.):

Cooling medium: Water

Number of IGBTs: 3

Power loss of each IGBT: 1 kW

Volume flow, overall: 0.15 l/s

Volume flow of each heat exchanger: 0.05 l/s

Density of water at 20° C.: 0.998 kg/l

Specific thermal capacity of water at 20° C.: 4182 J/(kg·K)

Temperature difference of each heat exchanger: 4.8 Kelvin

1-8. (canceled)

9. Cooling device for an electrical power component of a current. converter module, comprising:
a cooling circuit operated with a liquid coolant, wherein the power component produces the power loss P_{V} and the coolant has the density ρ and the specific thermal capacity c;
a heat exchanger, which is connected in the cooling circuit and to which the power component is coupled in a thermally conductive manner;
a cooler, which is connected in the cooling circuit for cooling the liquid coolant; and
a pump for maintaining a predetermined volume flow \dot{V} in the cooling circuit with a bridged heat exchanger;
wherein a plurality of pipelines is connected in parallel in the heat exchanger such that the temperature difference on the heat exchanger does not exceed the following value:
$$Δ T = \frac{Pv}{\dot{V} \cdot ρ \cdot c}$$

10. Cooling device according to claim 9, wherein the heat exchanger is configured to be plate-shaped.

11. Cooling device according to claim 9, wherein the power component is a bipolar transistor with an insulated-gate bipolar transistor (IGBT for short).

12. Cooling device according to claim 9, wherein the coolant is a water and ethanol mixture.

13. Cooling device according to claim 9, wherein during operation with a predetermined volume flow \dot{V}, the temperature difference on the heat exchanger is always below 10 Kelvin.

14. Cooling device according to claim 9, wherein during operation with a predetermined volume flow \dot{V}, the temperature difference on the heat exchanger is always below 5 Kelvin.

15. Wind power system, comprising:
a current converter module and having at least one electrical power component, which is cooled with a cooling device;
the cooling device comprising:
a cooling circuit operated with a liquid. coolant, wherein the power component produces die power loss P_{V} and die coolant has the density ρ and the specific thermal capacity c;
a heat exchanger, which is connected in the cooling circuit and to which the power component is coupled in a thermally conductive manner;
a cooler, which is connected in the cooling circuit for cooling the liquid coolant; and
a pump for maintaining a predetermined volume flow \dot{V} in the cooling circuit with a bridged heat exchanger;
wherein a plurality of pipelines is connected in parallel in the heat exchanger such that the temperature difference on the heat exchanger does not exceed the following value:
$$Δ T = \frac{Pv}{\dot{V} \cdot ρ \cdot c}$$
